(19) United States
(12) Patent Application Publication
(10) Pub. No.: US 2019/0198809 A1
(43) Pub. Date: Jun. 27, 2019

(54) THIN-FILM ENCAPSULATION STRUCTURE AND METHOD FOR OLED

(71) Applicant: Wuhan China Star Optoelectronics Semiconductor Display Technology Co., Ltd., Wuhan (CN)

(72) Inventor: Tianfu GUO, Shenzhen (CN)

(21) Appl. No.: 15/979,862

(22) Filed: May 15, 2018

Related U.S. Application Data
(63) Continuation of application No. PCT/CN2018/072696, filed on Jan. 15, 2018.

(30) Foreign Application Priority Data
Dec. 27, 2017 (CN) 201711448145.8

(51) Int. Cl. H01L 51/52; H01L 51/00; H01L 51/50

(52) U.S. Cl. CPC H01L 51/5256; H01L 51/5096; H01L 51/0002; H01L 51/0096

(57) ABSTRACT

Provided is a thin-film encapsulation structure for OLED, which includes a substrate loaded with an OLED, a first inorganic blocking layer, an organic buffer layer, and a second inorganic blocking layer. The refractive index of the first inorganic blocking layer is set to decrease along the direction from OLED to organic blocking layer, and the refractive index of organic blocking layer is smaller than that of first inorganic blocking layer, and the refractive index of second inorganic blocking layer is smaller than that of organic blocking layer. The refractive index change among the first inorganic blocking layer, the organic buffer layer, and the second inorganic blocking layer enhances the luminous efficiency and isolate the moisture and oxygen from entering OLED, prevents the interior of OLED from being corroded and improves thermal insulation effect. The organic buffer layer can wrap extrinsic substance in large particle and alleviate stress during planarization process.

### RELATED APPLICATIONS

This application is a continuation application of PCT Patent Application No. PCT/CN2018/072696, filed Jan. 15, 2018, which claims the priority benefit of Chinese Patent Application No. 201711448145.8, filed Dec. 27, 2017, which is herein incorporated by reference in its entirety.

### FIELD OF THE DISCLOSURE

The invention relates to the field of display panel technology, and more particularly to a thin-film encapsulation structure and method for organic light-emitting diode (OLED).

### BACKGROUND

Organic light-emitting diode (OLED) is a brand-new self-luminous display element with high brightness and full viewing angle. However, the metal electrodes of OLED are quite active and are prone to be contaminated by moisture and oxygen in the atmosphere. This would cause black dots on the display screen and seriously affect the lifespan of the element. Hence, the surface of OLED is required to be coated with a sealing layer consisting of a sealing material with excellent isolation capability against moisture and oxygen, so as to prolong the lifespan of OLED. Thus, thin-film encapsulation (TFE) has become a requisite encapsulation technique for OLED. A thin-film encapsulated OLED is advantageous in terms of wide color gamut, fast response characteristics, and high contrast ratio. As a result, OLED has been commonly employed in display applications.

Nowadays, the contemporary thin-film encapsulation technique adopts an encapsulation mode to stack inorganic metal oxides to form a composite thin-film encapsulation structure. Nonetheless, with the increase of the number of the thin-film layers, the stress on the encapsulated thin-film layers would grow as well, which would in turn crack the thin-film structure. As light is transmitting through different media, due to the discrepancy of refractive index, optical loss will be incurred as a result of the reflection occurred on the contact surface between media. The light of OLED will suffer a significant reflection loss after the light travels through an excessive number of films. Therefore, there is an urgency to develop a thin-film encapsulation structure with a good watertight and oxygen-tight capability without compromising the luminous efficiency of OLED.

### SUMMARY

In view of the aforementioned deficiencies, the invention is aimed to provide a thin-film encapsulation structure for OLED, which includes a first inorganic blocking layer, an organic buffer layer, and a second inorganic blocking layer, in which the change of the refractive index between these layers can suppress the occurrence of total reflection during light transmission and reduce the optical loss as a result of partial refraction. In this way, the luminous efficiency of OLED is enhanced, and the multi-layer structure of OLED is able to isolate the OLED element from outside moisture and oxygen that would corrode the interior of the OLED element. In the meantime, the thermal insulation effect of OLED is enhanced to avoid thermal damages to the OLED element in the subsequent deposition processes. In addition, the organic buffer layer can wrap extrinsic substance in large particle and alleviate the stress generated during the planarization process, so as to prolong the lifespan of element.

In a first aspect of the invention, a thin-film encapsulation structure for OLED is provided, which includes a substrate loaded with an OLED element, as well as a first inorganic blocking layer, an organic buffer layer, and a second inorganic blocking layer, all of which are sequentially coated on the OLED element. The refractive index of the first inorganic blocking layer is decreased along the direction from the OLED element to the organic buffer layer. The refractive index of the organic buffer layer is smaller than that of the first inorganic blocking layer. The refractive index of the second inorganic blocking layer is smaller than that of the organic buffer layer.

Alternatively, the refractive index of the first inorganic blocking layer is ranged from 1.7 to 1.9, and the refractive index of the organic buffer layer is ranged from 1.6 to 1.7, and the refractive index of the second inorganic blocking layer is ranged from 1.5 to 1.6. The refractive index of the first inorganic blocking layer is decreased along the direction from the OLED element to the organic buffer layer. The refractive index of the organic buffer layer is smaller than that of the first inorganic blocking layer. That is, the refractive index of the organic buffer layer is smaller than the minimum refractive index of the first inorganic blocking layer.

Alternatively, the material of the first inorganic blocking layer may include one or more of silicon nitride, aluminum nitride, zirconium nitride, titanium nitride, tantalum nitride, titanium oxide, aluminum oxynitride, and silicon oxynitride. The material of the second inorganic blocking layer may include one or more of silicon oxide, aluminum oxide, and silicon oxynitride. Alternatively, the material of the first inorganic blocking layer may include at least one of silicon nitride and silicon oxynitride, and the material of the second inorganic blocking layer may include at least one of aluminum oxide and silicon oxynitride.

Alternatively, the material of the organic buffer layer may include one or more of epoxy, acrolein resin, polyimide resin, polyethylene naphthalate, and polyethylene terephthalate.

Alternatively, the thickness of the first inorganic blocking layer is ranged from 100 nm to 2000 nm. The thickness of the organic buffer layer is ranged from 2 μm to 10 μm. The thickness of the second inorganic blocking layer is ranged from 1 μm to 3 μm. Alternatively, the thickness of the first inorganic blocking layer is ranged from 500 nm to 1500 nm, and the thickness of the organic buffer layer is ranged from 3 μm to 8 μm, and the thickness of the second inorganic blocking layer is ranged from 1.5p m to 3 μm.

Alternatively, the moisture vapor transmission rate for the thin-film encapsulation structure for OLED is (1-10)×10⁻⁵ g/m²/day.

In the first aspect of the invention, the refractive index change of the first inorganic blocking layer in the thin-film encapsulation structure, as well as the overall refractive index change among the first inorganic blocking layer, the organic buffer layer, and the second inorganic blocking layer of the thin-film encapsulation structure, can suppress the occurrence of total reflection and reduce the optical loss incurred due to partial refraction. Thus, the luminous efficiency of the OLED element is enhanced. This multi-layer encapsulation structure is able to prevent the outside moisture and oxygen from entering the OLED element and corroding the interior of the OLED element, and thereby attaining thermal insulation effect and preventing the OLED element from being thermally damaged in subsequent deposition processes. The organic buffer layer is able to wrap extrinsic substance in large particle and alleviate the stress generated during the planarization process, so as to prolong the lifespan of element.

In a second aspect of the invention, a thin-film encapsulation method for OLED is provided, which includes the steps of:

providing a substrate loaded with an OLED element and depositing a first inorganic blocking layer on the OLED element by atomic layer deposition process so as to cover the OLED element;

sequentially depositing an organic buffer layer and a second inorganic blocking layer on the first inorganic blocking layer, so as to obtain a thin-film encapsulation structure for OLED. The refractive index of the first inorganic blocking layer is decreased along the direction from the OLED element to the organic buffer layer. The refractive index of the organic buffer layer is smaller than that of the first inorganic blocking layer. The refractive index of the second inorganic blocking layer is smaller than that of the organic buffer layer.

Alternatively, the temperature during the atomic layer deposition process is gradually decreased from 100° C.-110° C. to 30° C.-50° C. Alternatively, the temperature during the atomic layer deposition process may be gradually decreased from 100° C.-105° C. to 30° C.-45° C.

Alternatively, the step of sequentially depositing an organic buffer layer and a second inorganic blocking layer on the first inorganic blocking layer includes the sub-steps of:

depositing an organic buffer layer on the first inorganic blocking layer by ink printing process or chemical vapor deposition process; and depositing a second inorganic blocking layer on the organic buffer layer by chemical vapor deposition process, physical vapor deposition process, or atomic layer deposition process.

The advantages of the invention will be expounded below. Part of the advantages can be easily understood by means of the detailed descriptions in the specification, and part of the advantages can be understood by putting the embodiment of the invention into practice.

### BRIEF DESCRIPTION OF THE DRAWINGS

To illustrate the embodiment of the invention or the technological scheme existed in the prior art in a clear manner, the accompanying drawings which are necessary for the illustration of the embodiment of the invention or prior art will be briefed below. The embodiment described herein is merely used for explicating the invention, but is not used for limiting the scope of the invention. In the figures:

FIG. 1 is a schematic diagram showing the thin-film encapsulation structure for OLED according to an embodiment of the invention;

FIG. 2 is a flow chart illustrating the thin-film encapsulation method for OLED according to an embodiment of the invention;

FIG. 3 is a schematic diagram for illustrating the procedural step of S101 in the thin-film encapsulation method for OLED according to an embodiment of the invention; and

FIG. 4 is a schematic diagram for illustrating the procedural step of S102 in the thin-film encapsulation method for OLED according to an embodiment of the invention.

### DETAILED DESCRIPTION OF PREFERRED EMBODIMENTS

A preferred embodiment of the invention will be described below. It should be pointed out that an artisan having ordinary skill in the art is able to make several modifications and alterations to the preferred embodiment without departing from the principle of the embodiment. These modifications and alterations should be deemed to be within the scope of the invention.

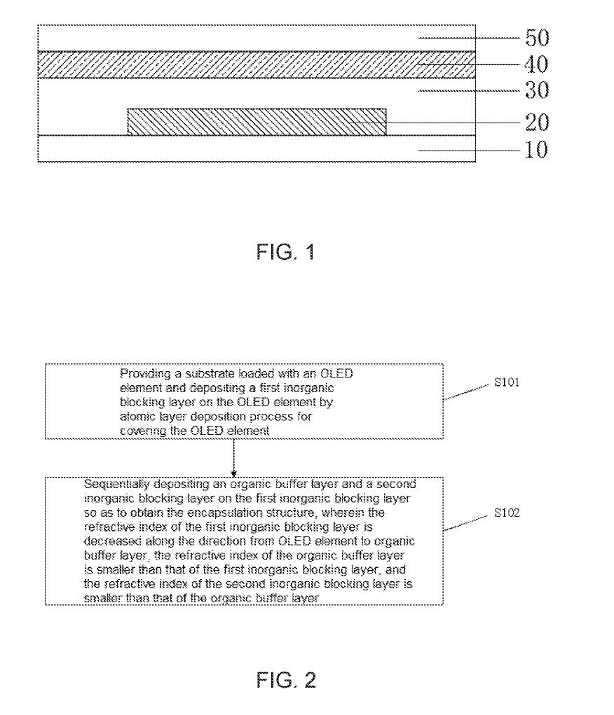

Please refer to FIG. 1, which shows the thin-film encapsulation structure for OLED according to the invention. The thin-film encapsulation structure includes a substrate 10 loaded with an OLED element 20, as well as a first inorganic blocking layer 30, an organic buffer layer 40, and a second inorganic blocking layer 50, all of which are sequentially coated on the OLED element 20. The refractive index of the first inorganic blocking layer 30 is decreased along the direction from the OLED element 20 to the organic buffer layer 40. The refractive index of the organic buffer layer 40 is smaller than that of the first inorganic blocking layer 30. The refractive index of the second inorganic blocking layer 50 is smaller than that of the organic buffer layer 40.

In this embodiment, the refractive index of the first inorganic blocking layer 30 is ranged from 1.7 to 1.9. The refractive index of the organic buffer layer 40 is ranged from 1.6 to 1.7. The refractive index of the second inorganic blocking layer 50 is ranged from 1.5 to 1.6. The refractive index of the first inorganic blocking layer 30 is decreased along the direction from the OLED element 20 to the organic buffer layer 40, and the refractive index of the organic buffer layer 40 is smaller than that of the first inorganic blocking layer 30. That is to say, the refractive index of the organic buffer layer 40 is smaller than the minimum refractive index of the first inorganic blocking layer 30.

In this embodiment, the material of the first inorganic blocking layer 30 may include one or more of silicon nitride, aluminum nitride, zirconium nitride, titanium nitride, tantalum nitride, titanium oxide, aluminum oxynitride, and silicon oxynitride. The material of the second inorganic blocking layer 50 may include one or more of silicon oxide, aluminum oxide, and silicon oxynitride. Alternatively, the material of the first inorganic blocking layer 30 may include at least one of silicon nitride and silicon oxynitride, and the material of the second inorganic blocking layer 50 may include at least one of aluminum oxide and silicon oxynitride.

In this embodiment, the material of the organic buffer layer 40 may include one or more of epoxy, acrolein resin, polyimide resin, polyethylene naphthalate, and polyethylene terephthalate.

In this embodiment, the thickness of the first inorganic blocking layer 30 is ranged from 100 nm to 2000 nm. The thickness of the organic buffer layer 40 is ranged from 2 μm to 10 μm. The thickness of the second inorganic blocking layer 50 is ranged from 1 μm to 3 μm. Alternatively, the thickness of the first inorganic blocking layer 30 is ranged from 500 nm to 1500 nm, and the thickness of the organic buffer layer 40 is ranged from 3 μm to 8 μm, and the thickness of the second inorganic blocking layer 50 is ranged from 1.5 μm to 3 μm.

In this embodiment, the moisture vapor transmission rate for the thin-film encapsulation structure for OLED is (1-10)×10⁻⁵ g/m²/day.

The internal refractive index change of the first inorganic blocking layer of the thin-film encapsulation structure for OLED, as well as the overall refractive index change among the first inorganic blocking layer, the organic buffer layer, and the second inorganic blocking layer, can enhance the luminous efficiency of the OLED element and isolate the OLED element from outside moisture and oxygen. Thus, the interior of the OLED element can be secure from corrosion and isolated form heat. More advantageously, the OLED element can be secure from thermal damage resulted from subsequent deposition processes. The organic buffer layer can wrap extrinsic substance in large particle and alleviate the stress generated during the planarization process, so as to prolong the lifespan of element.

Please refer to FIG. 2, which illustrates the thin-film encapsulation method for OLED according to an embodiment of the invention. The thin-film encapsulation method for OLED includes the following steps:

Step S101: providing a substrate loaded with an OLED element and depositing a first inorganic blocking layer on the OLED element by atomic layer deposition process so as to cover the OLED element;

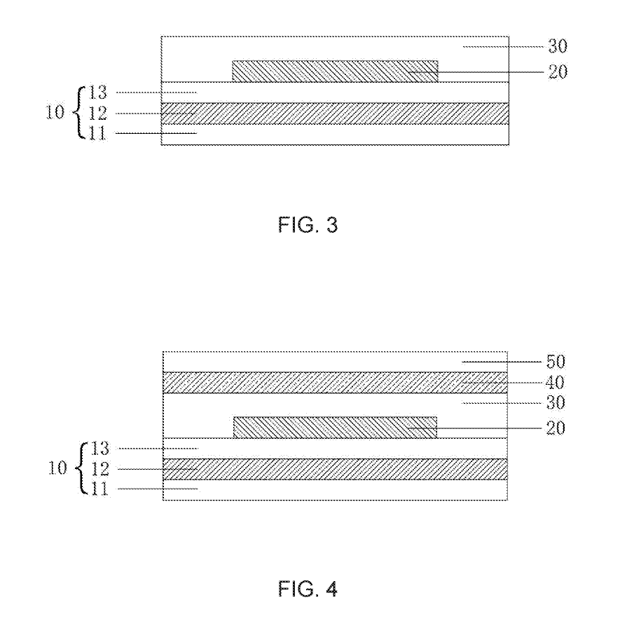

Please refer to FIG. 3. In the step S101, the substrate 10 is loaded with an OLED element 20. The substrate 10 may include a basal layer 11, as well as a buffer layer 12 and an inorganic film 13, both of which are sequentially deposited on the basal layer 11. The OLED element 20 is disposed on the inorganic film 13 and partially covers the inorganic film 13. In this embodiment, the first inorganic blocking layer 30 is deposited on the OLED element 20 by atomic layer deposition process so as to cover the OLED element 20. The temperature during the atomic layer deposition process is gradually decreased from 100° C.-110° C. to 30° C.-50° C. Alternatively, the temperature during the atomic layer deposition process may be gradually decreased from 100° C.-105° C. to 30° C.-45° C. The refractive index of the first inorganic blocking layer 30 is ranged from 1.7 to 1.9. The refractive index of the first inorganic blocking layer 30 is gradually decreased during the deposition process. That is to say, the refractive index of the first inorganic blocking layer 30 is decreased along the direction facing away from the OLED element 20. In this embodiment, the material of the first inorganic blocking layer 30 may include one or more of silicon nitride, aluminum nitride, zirconium nitride, titanium nitride, tantalum nitride, titanium oxide, aluminum oxynitride, and silicon oxynitride. Further. the material of the first inorganic blocking layer 30 may include at least one of silicon nitride and silicon oxynitride. The thickness of the first inorganic blocking layer 30 is ranged from 100 nm to 2000 nm. Alternatively, the thickness of the first inorganic blocking layer 30 is ranged from 500 nm to 1500 nm. The first inorganic blocking layer 30 covers the OLED element 20 and the area of the substrate 10 that is not covered by the OLED element 20.

Next, the step S102 is performed, in which:

Step 102: sequentially depositing an organic buffer layer and a second inorganic blocking layer on the first inorganic blocking layer, thereby implementing a thin-film encapsulating structure for OLED. The refractive index of the first inorganic blocking layer is decreased along the direction from the OLED element to the organic buffer layer. The refractive index of the organic buffer layer is smaller than that of the first inorganic blocking layer. The refractive index of the second inorganic blocking layer is smaller than that of organic buffer layer.

Please refer to FIG. 4. In the step S102, the organic buffer layer 40 is deposited on the first inorganic blocking layer 30 by ink printing process or chemical vapor deposition process. The second inorganic blocking layer is deposited on the organic buffer layer 40 by chemical vapor deposition process, physical vapor deposition process, or atomic layer deposition process. The embodiment of the invention proposes some feasible ways to deposit the organic buffer layer and the second inorganic blocking layer. Concretely speaking, the deposition of the organic buffer layer and the second inorganic blocking layer may be achieved by other known process, depending on practical needs. The material of the organic buffer layer 40 may include one or more of epoxy, acrolein resin, polyimide resin, polyethylene naphthalate, and polyethylene terephthalate. The refractive index of the organic buffer layer 40 is 1.6-1.7, and the thickness of the organic buffer layer 40 is ranged from 2 μm to 10 μm. Alternatively, the thickness of the organic buffer layer 40 is ranged from 3 μm to 8 μm. The material of the second inorganic blocking layer 50 may include one or more of silicon oxide, aluminum oxide, and silicon oxynitride. Alternatively, the material of the second inorganic blocking layer 50 may include one or more of aluminum oxide and silicon oxynitride. The refractive index of the second inorganic blocking layer 50 is ranged from 1.5 to 1.6, and the thickness of the second inorganic blocking layer 50 is ranged from 1 μm to 3 μm. Alternatively, the thickness of the second inorganic blocking layer 50 is ranged from 1.5 μm to 3 μm. The refractive index of the organic buffer layer 40 is smaller than that of the first inorganic blocking layer 30. That is, the refractive index of the organic buffer layer 40 is smaller than the minimum refractive index of the first inorganic blocking layer 30. The refractive index of the second inorganic blocking layer 50 is smaller than that of the organic buffer layer 40.

In this embodiment, the moisture vapor transmission rate for the thin-film encapsulation structure for OLED is (1-10)×10⁻⁵ g/m²/day.

The invention provides a thin-film encapsulation method for OLED with simple and mature manufacturing process for massive production in factory.

The foregoing embodiment merely elaborates several practical ways to accomplish the invention in a concrete and precise manner. However, it is not to be interpreted as the limitation to the scope of the invention. It should be pointed out that an artisan having ordinary skill in the art is able to make some modifications and improvements on the embodiment without departing from the conception of the invention, and these modifications and improvements should be fallen within the scope of the invention. The scope of the invention should be defined by the appended claims.

What is claimed is:

1. A thin-film encapsulation structure for organic light-emitting diode (OLED), comprising:
a substrate loaded with an OLED element; and
a first inorganic blocking layer, an organic buffer layer, and a second inorganic blocking layer, all of which are sequentially coated on the OLED element;
wherein a refractive index of the first inorganic blocking layer is set to decrease along the direction from the OLED element to the organic blocking layer, and a refractive index of the organic blocking layer is smaller than that of the first inorganic blocking layer, and a refractive index of the second inorganic blocking layer is smaller than that of the organic blocking layer.

2. The thin-film encapsulation structure for organic light-emitting diode (OLED) according to claim 1, wherein the refractive index of the first inorganic blocking layer is ranged from 1.7 to 1.9, and the refractive index of the organic buffer layer is ranged from 1.6 to 1.7, and the refractive index of the second inorganic blocking layer is ranged from 1.5 to 1.6.

3. The thin-film encapsulation structure for organic light-emitting diode (OLED) according to claim 1, wherein the material of the first inorganic blocking layer includes one or more of silicon nitride, aluminum nitride, zirconium nitride, titanium nitride, tantalum nitride, titanium oxide, aluminum oxynitride, and silicon oxynitride, and wherein the material of the second inorganic blocking layer includes one or more of silicon oxide, aluminum oxide, and silicon oxynitride.

4. The thin-film encapsulation structure for organic light-emitting diode (OLED) according to claim 3, wherein the material of the first inorganic blocking layer includes at least one of silicon nitride and silicon oxynitride, and wherein the material of the second inorganic blocking layer includes at least one of aluminum oxide and silicon oxynitride.

5. The thin-film encapsulation structure for organic light-emitting diode (OLED) according to claim 1, wherein the material of the organic buffer layer includes one or more of epoxy, acrolein resin, polyimide resin, polyethylene naphthalate, and polyethylene terephthalate.

6. The thin-film encapsulation structure for organic light-emitting diode (OLED) according to claim 1, wherein the thickness of the first inorganic blocking layer is ranged from 100 nm to 2000 nm, and wherein the thickness of the organic buffer layer is ranged from 2 μm to 10 μm, and wherein the thickness of the second inorganic blocking layer is ranged from 1 μm to 3 μm.

7. The thin-film encapsulation structure for organic light-emitting diode (OLED) according to claim 1, wherein the moisture vapor transmission rate for the thin-film encapsulation structure for OLED is (1-10)×10⁻⁵ g/m²/day.

8. A thin-film encapsulation method for organic light-emitting diode (OLED), comprising:
providing a substrate loaded with an OLED element and depositing a first inorganic blocking layer on the OLED element by an atomic layer deposition process, so as to cover the OLED element;
sequentially depositing an organic buffer layer and a second inorganic blocking layer on the first inorganic blocking layer so as to attain a thin-film encapsulation structure for OLED, wherein a refractive index of the first inorganic blocking layer is set to decrease along the direction from the OLED element to the organic blocking layer, and a refractive index of the organic blocking layer is smaller than that of the first inorganic blocking layer, and a refractive index of the second inorganic blocking layer is smaller than that of the refractive index of the organic blocking layer.

9. The thin-film encapsulation method for organic light-emitting diode (OLED) according to claim 8, wherein the temperature during the atomic layer deposition process is gradually decreased from 100° C.-110° C. to 30° C.-50° C.

10. The thin-film encapsulation method for organic light-emitting diode (OLED) according to claim 8, wherein the step of sequentially depositing an organic buffer layer and a second inorganic blocking layer on the first inorganic blocking layer includes the sub-steps of:
depositing an organic buffer layer on the first inorganic blocking layer by an ink printing process or a chemical vapor deposition process; and
depositing a second inorganic blocking layer on the organic buffer layer by a chemical vapor deposition process, a physical vapor deposition process, or an atomic layer deposition process.
